(19) United States
(12) Patent Application Publication
(10) Pub. No.: US 2007/0132471 A1
(43) Pub. Date: Jun. 14, 2007

(54) Method and apparatus for testing integrated circuits over a range of temperatures

(76) Inventor: Gregory Frank Carlson, Corvallis, OR (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/300,545

(22) Filed: Dec. 13, 2005

(51) Int. Cl. G01R 31/02

(52) U.S. Cl. 324/763

(57) ABSTRACT

A method, system and device for testing an integrated circuit or device under test over a range of temperatures with a plunger, clamp or lid over the integrated circuit or device under test is disclosed.

### BACKGROUND

This invention relates to the field of devices, systems and methods for testing electronic circuits by applying and measuring electrical signals, and more particularly to devices, systems and methods for testing systems-on-a-chip (SOC) or other integrated circuits. To ensure proper functionality and reliability, manufacturers typically test SOC integrated circuits (ICs) before shipping SOC ICs to customers. One system commonly employed to test SOC ICs is the Agilent Technologies, Inc. 93000 SOC Tester. Portions of the Agilent 93000 SOC Tester are described in U.S. Pat. No. 6,756,778 to Hirschmann entitled “Measuring and/or Calibrating a Test Head”; U.S. Pat. No. 5,558,541 to Botka et al. entitled “Blind Mate Connector for an Electronic Circuit Tester”; and U.S. Pat. No. 5,552,701 to Veteran et al. entitled “Docking System for an Electronic Circuit Tester”.

FIG. 1 shows the Agilent 93000 Tester 100, comprising a test head 110 with a device under test (DUT) interface 120; a manipulator 130 for positioning test head 110; a DUT board 150 that plugs into underlying DUT interface 120; a support rack 140 for supplying test head 110 with electrical power, water cooling and compressed air (not shown) and a computer workstation (not shown) that serves as the user interface to Tester 100. Test head 110 comprises tester electronics and additional analog modules. With current technology, test head 110 may be configured with 512 pins or 1024 pins, but this will likely increase in the future. The 512 pin test head supports 4 card cages while the 1024 pin test head supports 8 card cages. Each card cage may contain 8 digital boards or 8 analog modules, respectively. A single board has 16 pins, making 128 pins per cage. Thus, a 4-cage test head contain 512 pins and an 8-cage test head 1024 pins. During testing, a DUT is mounted on a contactor (not shown) on the DUT board 150, which is connected to the I/O channels by DUT interface 120. DUT interface 120 may comprise high performance coax cabling and spring contact pins or pogo pins, which establish electrical connection with DUT board 120.

DUT interface 120 provides docking capabilities to handlers and wafer probers. The docking mechanism is controlled by compressed air (not shown), and if required may also be operated manually. Test head 110 is usually a water-cooled system and receives its cooling water supply from support rack 140, which in turn is connected by two flexible hoses to the cooling unit (not shown). Manipulator 130 supports and positions test head 110 and provides 6 degrees of freedom for precise and repeatable connections between test head 100 and handlers or wafer probers.

Support rack 140 is attached to manipulator 130 and serves as the interface between test head 110 and an AC power source, cooling water source and compressed air source. Tester 100 may also comprise additional support racks such as analog support racks for installing additional analog instruments.

It would be advantageous if an SOC tester were able to test SOC and other ICs over a range of temperatures, as some faults can only detected at higher or lower temperatures.

### BRIEF DESCRIPTION OF THE DRAWINGS

An understanding of the present teachings can be gained from the following detailed description, taken in conjunction with the accompanying drawings of which:

FIG. 1 illustrates the Agilent Technologies, Inc. 93000 SOC Tester.

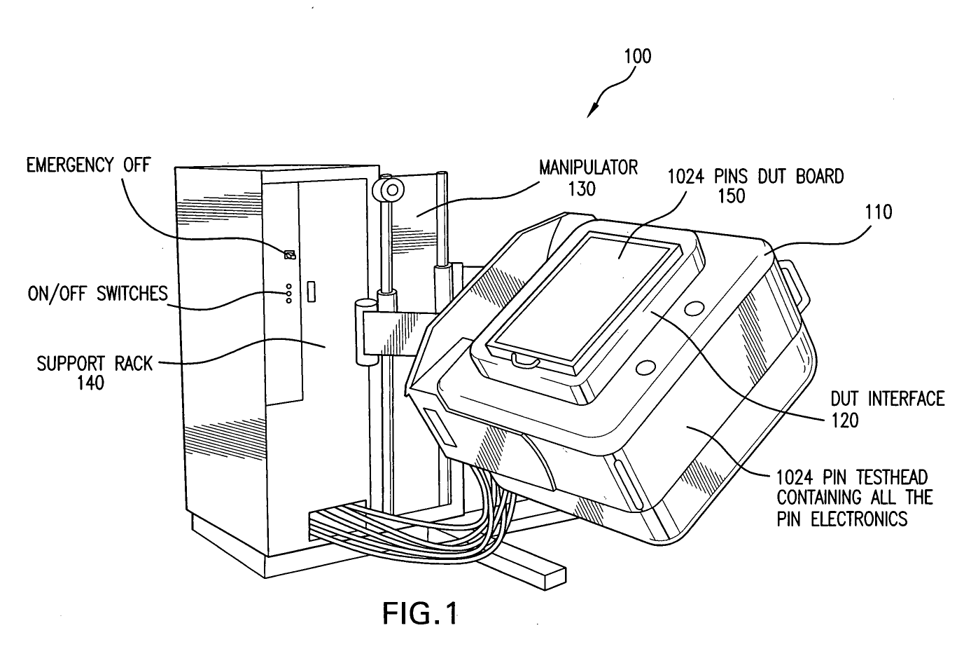

FIG. 2 shows a perspective view of a test head with a probe or DUT board and a DUT contactor or socket thereon.

FIG. 3 shows a side cut-away view of a DUT contactor or socket with a DUT held thereon by a plunger, clamp or DUT lid.

FIG. 4 shows a side cut-away view of a DUT contactor or socket with a DUT held thereon by a plunger, clamp or DUT lid with a heating and cooling device.

### DETAILED DESCRIPTION

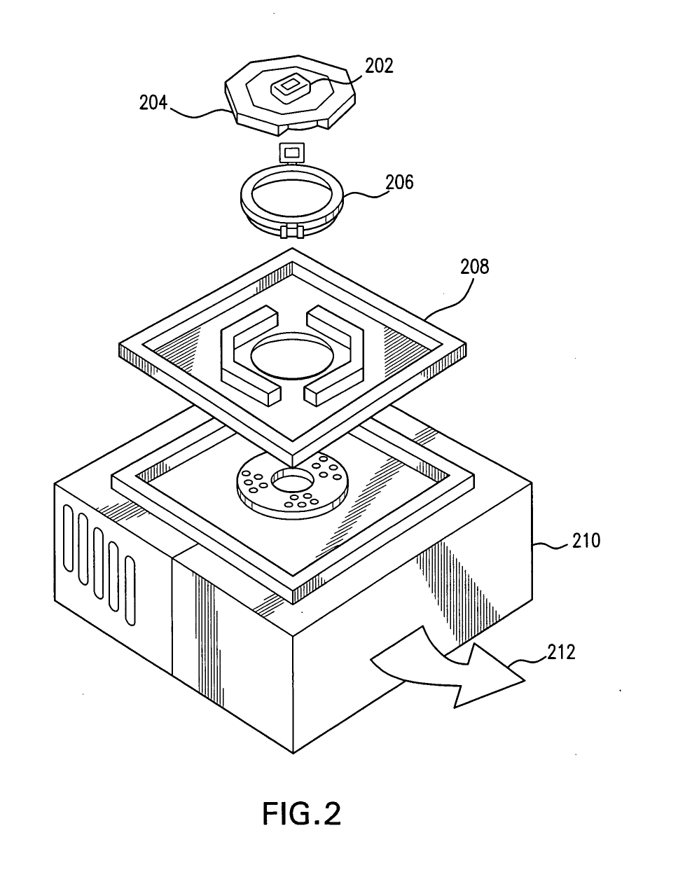

FIG. 2 shows a typical contactor 202 mounted on a probe or DUT board 204. The probe or DUT board 204 may be secured to a load board 108 with a connecting collar 206. The load board 204 is mounted to a test head 210. The test head 210 communicates with a test system (not shown) be a cable assembly 212 or other data transmission means. The contactor 202 enables the balls or leads of a DUT (not shown) to make electrical contact to the DUT or probe board 204.

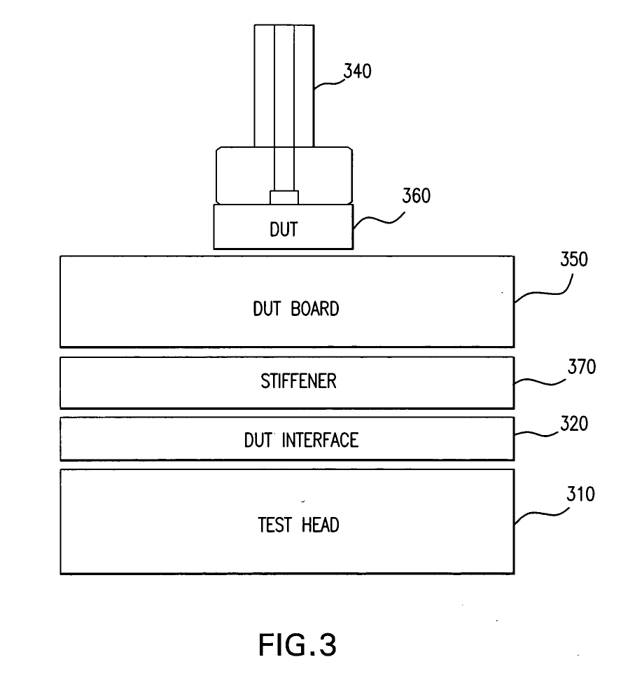

FIG. 3 shows a typical DUT plunger, lid or clamp 340 securing a DUT 360 to a DUT or probe board 350. The DUT plunger, lid or clamp keeps the DUT secured to the DUT board 350 during the testing process. The DUT board 350 may include a socket or contactor as shown in FIG. 2. There may be a stiffener 370 between the DUT board 350 and the DUT interface 320. The DUT interface 320 provides an interface between the DUT board 350 and the test head 310. Throughout this document, a DUT plunger may also be referred to as a DUT lid or clamp, but they will be the same device.

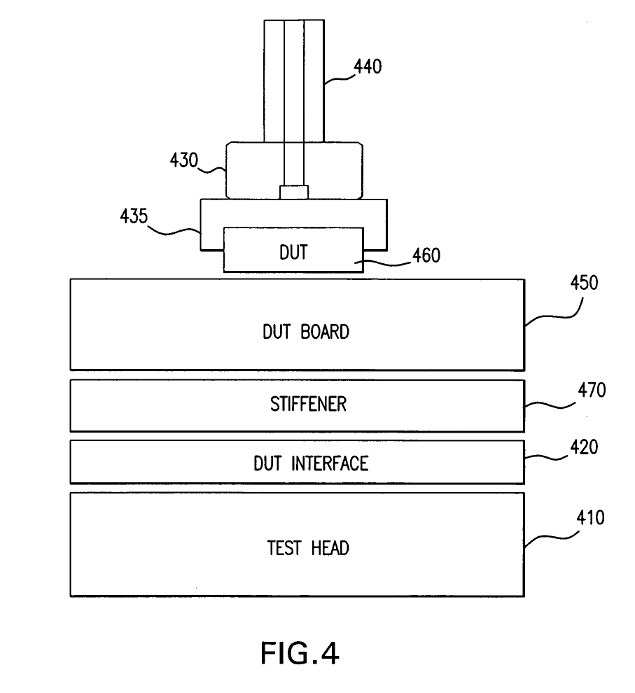

FIG. 4 shows a DUT lid 440 with a temperature control device 430. The DUT lid secures the DUT 460 onto the DUT board 450 during the testing process. There may also be a stiffener 470 and a DUT interface 420 between the DUT board 450 and the test head 410. The temperature control device 430 may be integral with the DUT lid 440 and may provide heating and cooling to the DUT 460 during the testing process, so that the DUT 460 may be tested over a range of temperatures. The temperature control device 430 may include a sleeve 435 on one, two, three or four sides, to provide guidance when the DUT lid 440 comes into contact with the DUT 460. Sleeve 435 may also further surround the DUT 460 for greater temperature control during the testing process. The temperature control device 430 may include thermal grease or thermal paste between the temperature control device 430 and the DUT lid 440 or between the temperature control device 430 and the DUT 460.

The temperature control device 430 may be a peltier device or a thermoelectric module, which are generally small solid state devices that function as heat pumps. A typical peltier device is a small unit that is a few millimeters thick by a few millimeters to a few centimeters square. It is a sandwich formed by two ceramic plates with an array of small Bismuth Telluride (Bi₂Te₃) cubes or couples in between. When DC current is applied, heat is moved from one side of the device to the other, where it may be removed with a heat sink. The lid 440 may act as the heat sink. The current may be reversed to provide heat to the DUT during testing.

Thus, it will be readily appreciated by those in the art that the DUT lid 440 with the temperature control or peltier device 430 may be used to heat or cool the DUT during testing, depending on the direction of the power supply. The temperature rating for most peltier devices is 80 C or 200 C for high temperature models. Peltier devices can change temperature extremely quickly. The temperature can be controlled by varying the power supply with a temperature sensor feedback, such as a thermistor or a solid state sensor and a closed loop control circuit. Also, the DUT lid or plunger 440 may also act as a heat sink, if necessary to dissipate excess heat, when the DUT is being cooled.

The temperature controlled lid may be formed with other similarly small heating and cooling devices, besides a peltier device. The temperature control device may be used in other integrated circuit testers and could be used in any type of tester from prototype, printed circuit board, manufacturing or in the lab testing.

1. A system for testing a semiconductor device (DUT) over a range of temperatures, comprising:
a test head;
a DUT interface on the test head;
a DUT board on the DUT interface;
a DUT lid for holding the DUT on the DUT board, the DUT lid having a temperature control device and a guidance sleeve attached to the DUT lid which guides the DUT lid relative to the DUT as the DUT lid is brought into contact with the DUT and which encircles the DUT when the DUT is secured to the DUT board by the DUT lid.

2. The system for testing the semiconductor device (DUT) over a range of temperatures according to claim 1, wherein the temperature control device comprises a peltier device.

3. (canceled)

4. The system for testing a semiconductor device (DUT) over a range of temperatures according to claim 1, wherein the DUT lid comprises a heat sink.

5. The system for testing a semiconductor device (DUT) over a range of temperatures according to claim 1, wherein the test head is an SOC test head.

6. The system for testing a semiconductor device (DUT) over a range of temperatures according to claim 1, wherein the temperature control device comprises a temperature-sensing device for closed-loop temperature control.

7. A method for testing a semiconductor device (DUT) over a range of temperatures, the method comprising of the following steps:
placing a DUT on a DUT board on a test head;
securing the DUT to the DUT board with a DUT lid, the DUT lid having a temperature control device and a guidance sleeve attached to the DUT lid which guides the DUT lid relative to the DUT as the DUT lid is brought into contact with the DUT and which encircles the DUT when the DUT is secured to the DUT board by the DUT lid;
heating or cooling the DUT with the temperature control device;
and testing the DUT.

8. The method according to claim 7, wherein the step of heating or cooling and the step of testing may be run simultaneously.

9. The method according to claim 7, wherein the temperature control device is a peltier device and the step of heating or cooling comprises running a current in one or the other direction through the peltier device.

10. (canceled)

11. The method according to claim 10, wherein the DUT lid comprises a heat sink for the temperature control device.

12. The method according to claim 7, further comprising the step of controlling the temperature with a temperature sensing device and a closed-loop temperature circuit.
